(19) United States
(12) Patent Application Publication
(10) Pub. No.: US 2009/0184773 A1
(43) Pub. Date: Jul. 23, 2009

(54) Hybrid Pll Combining Fractional-N & Integer-N Modes of Differing Bandwidths

(75) Inventors: Kyoungho Woo, Cambridge, MA (US); Ham Donhee, Cambridge, MA (US)

Correspondence Address: WOLF GREENFIELD & SACKS, P.C., 600 ATLANTIC AVENUE, BOSTON, MA, 02210-2206, US

(73) Assignee: President and Fellows of Harvard College, Cambridge, MA (US)

(21) Appl. No.: 12/224,904

(22) PCT Filed: Mar. 9, 2007
(86) PCT No.: PCT/US2007/006134

§ 371 Date: Dec. 15, 2008

Related U.S. Application Data
(60) Provisional application No. 60/781,454, filed on Mar. 10, 2006.

(51) Int. Cl. H03L 7/099

(52) U.S. Cl. 331/1 R

(57) ABSTRACT

A single-loop PLL that operates in a narrower-bandwidth, integer-N mode during phase lock and in a wider-bandwidth, fractional-N mode during transient. This hybrid PLL simultaneously achieves the fast-locking advantage of the fractional-N PLL and design simplicity of the integer-N PLL. The frequency division mode switching facilitates a digital protocol to execute bandwidth switching, which increases the degree of design freedom for the bandwidth switching.

### PRIORITY

This application claims priority to U.S. Provisional Application Ser. No. 60/781,454, filed Mar. 10, 2006, entitled “Fastlock Integer/Fractional-N Hybrid PLL Frequency Synthesizer,” which is hereby incorporated herein by reference.

### GOVERNMENT-SPONSORED RESEARCH

Some of the research relating to the subject matter disclosed herein was sponsored by the United States National Science Foundation, award nos. NSF-ECS-0313143 and NSF-PHY-06-46094, the United States Army Research Office, award no. W911NF-06-1-0290, and the United States Air Force Office of Scientific Research, award no. FA 950-06-1-0305, and the United States government may have certain rights to some disclosed subject matter.

### BACKGROUND

Bandwidth exerts key influences on the dynamics of phase-locked loop (PLL) frequency synthesizers, especially the popular charge-pump PLL frequency synthesizers. Important characteristics of PLL frequency synthesizers which are critically affected by bandwidths include lock time and output spectrum.

For example, a wider loop bandwidth directly translates to faster locking (i.e., shorter lock time) and, therefore, in many implementations bandwidth is maximized to minimize the lock time. In particular, to ensure loop stability, the upper frequency bound of a PLL typically is set to about 10 percent of the reference frequency, f_{REF}. Too large a loop bandwidth, however, brings more spurs and component noise into the PLL dynamics, corrupting the output spectrum. Accordingly, the bandwidth to attain optimal spectrum is usually smaller than 0.1f_{REF}. As may be seen in many PLL implementations, maximizing the bandwidth to achieve the fastest locking possible contradicts the need for a smaller bandwidth for optimum in-band spectrum.

One conventional solution to this difficulty is a PLL frequency synthesizer incorporating a variable-bandwidth scheme. In this PLL, a wider bandwidth is used during transient to accelerate phase locking, but once a phase lock is reached and the PLL enters a steady state, the bandwidth is shifted to a smaller value to obtain optimum spectrum. This bandwidth-control scheme exploits the fact that the lock time matters only during transient while the spectral purity is important only in steady state.

Almost all of these utilizations of the variable-bandwidth PLL scheme, however, have so far been limited to a fixed frequency division mode operation, i.e., the bandwidth switching has been executed while maintaining the same frequency division mode (integer- or fractional-N). For a given frequency resolution, the fractional-N PLL has a larger reference frequency—the frequency of the crystal-oscillator-derived signal at an immediate input of a phase frequency detector—than the integer-N PLL. Therefore, the transient-state bandwidth, limited to 10 percent of the reference frequency as discussed above, is larger in the variable-bandwidth fractional-N PLL than in its integer-N counterpart. As a result, the former assumes a locked state faster than the latter.

The faster locking of the fractional-N PLL, however, comes at the price of increased design complexity. This is because the fractional-N operation in steady state requires phase interpolators or higher-order ΣΔ modulators to mitigate fractional spurs. In the presence of such spur suppression circuits, whose quantization noise folds into and adds phase noise to the PLL spectrum via the loop nonlinearities, more significant design efforts are required to minimize the loop nonlinearities. This design complexity of the fractional-N PLL is further compounded by the fact that the negative, nonlinearity-mediated impact of the quantization noise is very difficult to predict. In contrast, integer-N PLLs involve much less design complexity as there is no need for fractional spur suppression circuits due to the absence of such spurs.

### SUMMARY

The present disclosure is directed generally to a single-loop PLL that operates in a narrower-bandwidth, integer-N mode during phase lock and in a wider-bandwidth, fractional-N mode during transient. This hybrid PLL simultaneously achieves the fast-locking advantage of the fractional-N PLL and design simplicity of the integer-N PLL. The frequency division mode switching facilitates a digital protocol to execute bandwidth switching, which increases the degree of design freedom for the bandwidth switching.

In particular, one embodiment is directed to an apparatus to synthesize a frequency. The apparatus comprises a phase-frequency detector (PFD) to receive a first and a second input, a charge pump coupled to the PFD, a loop filter coupled to the charge pump, and a voltage-controlled oscillator (VCO) coupled to the loop filter. The apparatus further comprises a feedback loop coupled to the VCO and the second input of the PFD, and a lock timer to control the at least one multiplexer. The feedback loop comprises at least one accumulator, at least one multiplexer that provides the second input to the PFD, and at least one static divider coupled to the multiplexer and configured to manipulate the second input to the PFD.

Another embodiment is directed to a method comprising operating a PLL circuit in a first frequency division mode during a transient state and operating the PLL circuit in a second frequency division mode once the PLL circuit reaches a steady state.

Another embodiment is directed to an apparatus to synthesize a frequency. The apparatus comprises a phase-frequency detector (PFD) to receive a first and a second input, a charge pump coupled to the PFD, a loop filter coupled to the charge pump, and a voltage-controlled oscillator (VCO) coupled to the loop filter. The apparatus further comprises a controller to change an operating mode of the apparatus between a fractional-N mode and an integer-N mode.

It should be appreciated that all combinations of the foregoing concepts and additional concepts discussed in greater detail below are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

FIG. 1 is a conceptual illustration of the operation of a hybrid PLL according to embodiments of the present invention;

FIG. 2A is a circuit diagram showing an exemplary implementation of the fractional-N mode of a hybrid PLL in accordance with embodiments of the present invention;

FIG. 2B is a circuit diagram showing an exemplary implementation of the integer-N mode of a hybrid PLL in accordance with embodiments of the present invention;

FIG. 2C is a timing diagram showing exemplary responses of signals of the hybrid PLL in accordance with embodiments of the present invention;

FIG. 2D is a circuit diagram showing a conventional implementation of an integer-N PLL;

FIG. 3A is a general charge-pump model of a second-order loop filter implemented in accordance with one embodiment of the invention;

FIG. 3B is a bode plot of both the magnitude and phase of the open loop transfer function of the exemplary charge-pump model of FIG. 3A;

FIG. 3C is an exemplary implementation of a second-order loop filter with a switch in accordance with one embodiment of the present invention;

FIG. 4 is a circuit diagram of the overall architecture of an exemplary hybrid PLL in accordance with one embodiment of the present invention;

FIG. 5A is a circuit diagram of an exemplary prescaler to be used in accordance with one embodiment of the present invention;

FIG. 5B is a circuit diagram of an exemplary static divider to be used in accordance with one embodiment of the present invention;

FIG. 6 is a circuit diagram of an exemplary voltage controlled oscillator to be used in accordance with one embodiment of the present invention;

FIG. 7 is a circuit diagram of an exemplary charge pump to be used in accordance with one embodiment of the present invention;

FIG. 8 is a circuit diagram of an exemplary phase frequency detector to be used in accordance with one embodiment of the present invention;

FIG. 9A is a graph comparing the evolution of the phase error of PLL circuits for both an exemplary hybrid PLL in accordance with embodiments of the present invention and a conventional integer-N PLL;

FIG. 9B is a timing diagram showing voltage signals in the steady-state fractional-N mode of an exemplary hybrid PLL in accordance with embodiments of the present invention;

FIG. 10A is a timing diagram showing signals throughout the circuit of an exemplary hybrid PLL in accordance with one embodiment of the present invention;

FIG. 10B is a timing diagram showing signals throughout the circuit of an exemplary hybrid PLL in accordance with one embodiment of the present invention;

FIG. 11 is a graph comparing the settling transients for both an exemplary hybrid PLL in accordance with embodiments of the present invention and a conventional integer-N PLL;

FIG. 12A is a graph showing the measured power spectral density of an exemplary hybrid PLL in steady-state, integer-N mode in accordance with one embodiment of the present invention; and

FIG. 12B is a graph showing the measured phase noise of the circuit of FIG. 12A in accordance with one embodiment of the present invention.

### DETAILED DESCRIPTION

Applicants have appreciated that conventional solutions to the problem of simultaneously reducing lock time, increasing bandwidth, and controlling spectrum noise in phase-locked loop (PLL) circuits have been limited, to a fixed frequency division mode operation, i.e., the bandwidth switching has been executed while maintaining the same frequency division mode (integer- or fractional-N). Applicants have further appreciated the desirability of a new PLL that changes not only the bandwidth but also the frequency division mode in transitions between transient and steady states.

In view of the foregoing, one embodiment of the present invention is directed to a hybrid PLL circuit which operates in an integer-N mode during phase lock (steady state) but in a fractional-N mode during transient. In embodiments of the invention, the hybrid PLL changes not only bandwidth but also the frequency division mode in transitions between transient and steady states. In addition, the hybrid PLL simultaneously achieves the fast-locking advantage of the fractional-N PLL and the design-simplicity benefit of the integer-N PLL. The combination of the two frequency division modes of differing bandwidths brings benefits to certain PLL applications, which will be described below.

Previous attempts at implementing PLLs which employ a frequency division mode switching between transient and steady states differ in significant ways from the hybrid PLL according to embodiments of the present invention. For example, in “A dual-band frequency synthesizer for 802.11a/b/g with fractional-spur averaging technique” by S. Pellerano et al., while the frequency division mode is changed from fractional-N to what is similar to integer-N at the onset of a steady state, the primary goal is not fast locking, but on fractional spur removal, and neither systematic nor significant attempt for bandwidth switching is made. In addition, although the Pellerano steady-state loop configuration yields what a standard integer-N PLL would yield in terms of output, the inner workings of the former are far different from the latter. This makes the architecture of Pellerano's PLL significantly deviate from the hybrid PLL architecture.

In “New fast-lock PLL for mobile GSM GPRS applications” by B. Memmler et al., while the motivation is fast locking and their PLL employs a switching between integer-N and fractional-N in a single loop as in the hybrid PLL, the bandwidth is deliberately maintained at the same level, not fully exploiting the speed advantage of the hybrid approach. For fast locking, Memmler et al. relied on the fact that the fractional-N mode has more phase comparison events per unit time than the integer-N mode due to the former's increased reference frequency, which is naturally exploited in the hybrid design as well. However, this is not as powerful as bandwidth increase in terms of enhancing locking speed. In addition, for the maintenance of the same bandwidth, Memmler used a fixed loop filter and incorporated an additional charge pump with a switch to decrease the charge pump current to offset the automatic reduction in N_{D} when the PLL is switched to a fractional-N mode at the onset of a transient. This is topologically and operationally in striking contrast with the hybrid PLL, the architecture and operation of which is discussed in greater detail below.

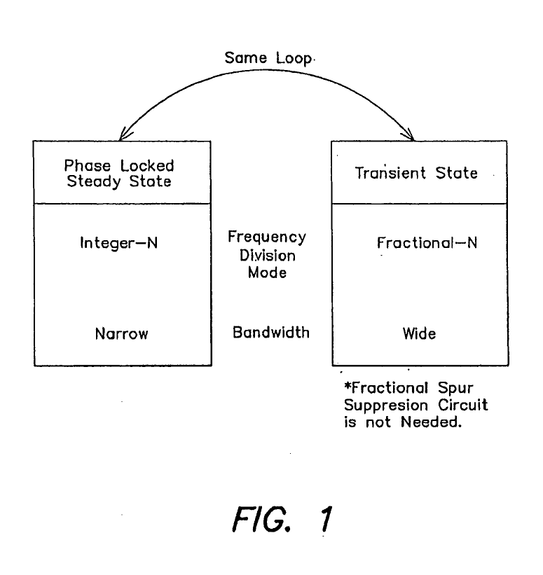

FIG. 1 is a conceptual illustration of a hybrid PLL operating according to one embodiment of the present invention. As shown, the hybrid PLL operates in an integer-K mode during the steady state, but operates in a fractional-N mode with a wider bandwidth during transient. The fast locking is the natural outcome of the wider-bandwidth fractional-N operation during transient which is enabled by the fractional-N mode's accommodation of a wider bandwidth due to its larger reference frequency.

In the conventional variable-bandwidth PLL, there are two building blocks that are reconfigured to alter the loop bandwidth, namely the charge-pump (its current) and the loop filter (its component values). In the hybrid PLL, the frequency division ratio shift naturally arising from the frequency division mode switching serves as an additional parameter to change the loop bandwidth. This approach thus allows for a new protocol for altering the loop bandwidth, using not only the conventional parameters (charge pump current and loop filter components) but also the frequency division ratio. This allows for designers to explore a larger design space in terms of bandwidth switching. Depending on specific design goals, one can properly proportion the changes in the loop filter components, charge pump current, and the frequency division ratio to alter the bandwidth. For instance, in the case where the bandwidth is changed by a large amount, this new protocol can lessen the burden of the large change in the charge-pump current, as the frequency division ratio change can also contribute to the bandwidth change.

One especially interesting usage of this new bandwidth-switching protocol is to use solely the frequency division ratio change while maintaining the same charge-pump current. This is interesting because it represents an execution of the bandwidth switching in a more digital fashion as the analog charge-pump circuit does not have to be reconfigured at all. This bandwidth switching with the constant charge-pump current, made possible by the frequency division ratio change in the hybrid PLL, also represents a polar opposite of the conventional bandwidth-switching scheme in which the charge-pump current must be modified along with the reconfiguration of the loop filter to alter the bandwidth. In a CMOS implementation of the hybrid PLL according to one embodiment of the present disclosure, this constant-charge-pump-current bandwidth-switching protocol is used.

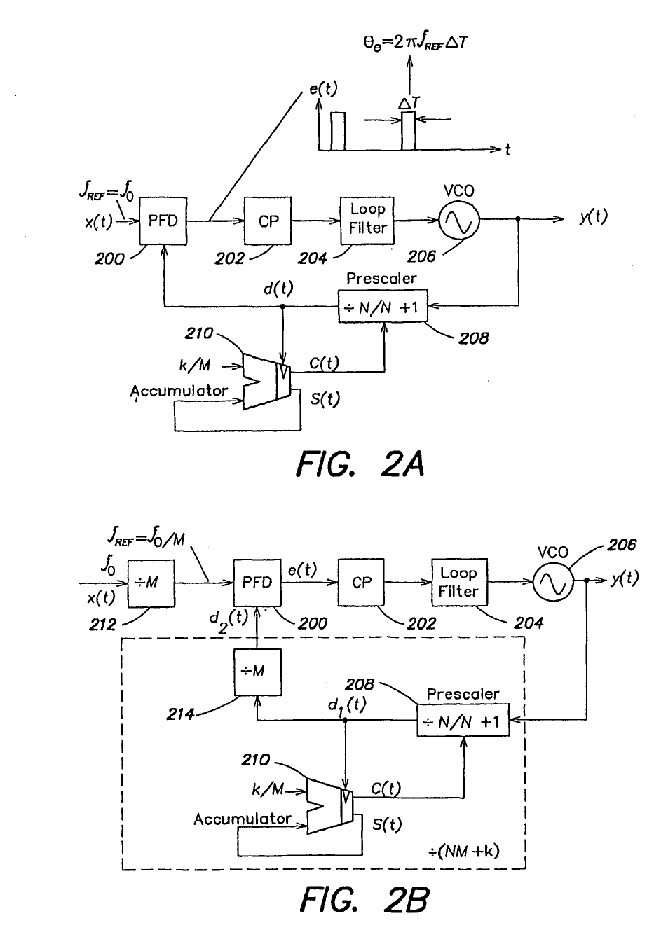

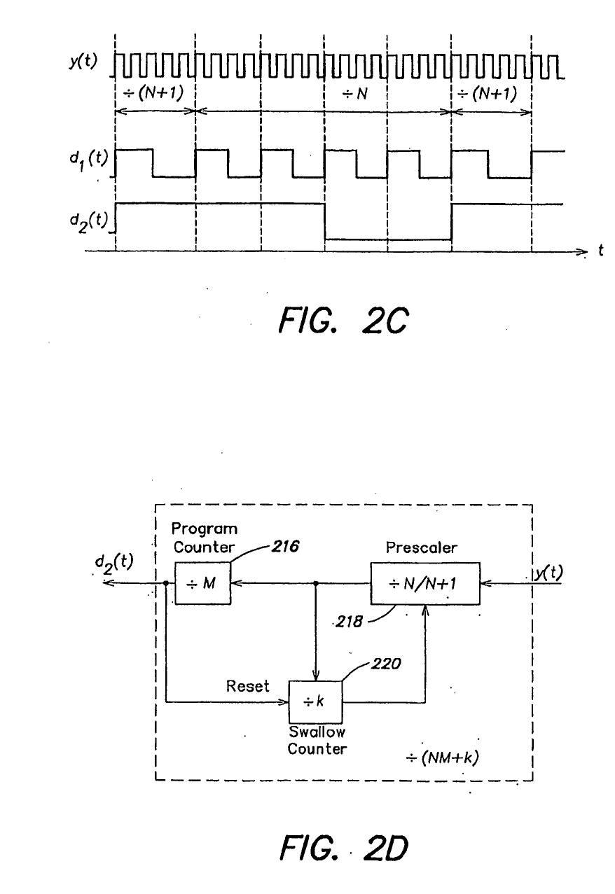

With reference to FIGS. 2A, 2B, 2C, and 2D, the basic scheme to switch between the fractional-N and integer-N mode in a single loop is explained. Both modes are to produce the same identical set of output frequencies with the same frequency resolution.

FIG. 2A shows an illustrative implementation of the fractional-N mode operation of the hybrid PLL which is used during transient. It should be appreciated that the circuit schematic of FIG. 2A is merely exemplary, and that other implementations are possible.

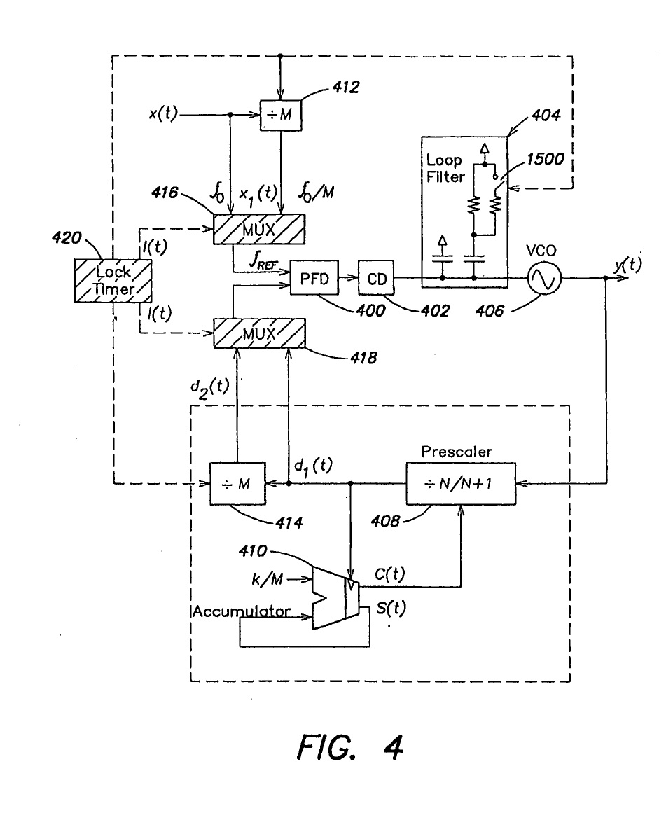

The circuit of FIG. 2A comprises a phase-frequency detector (PFD) 200, a charge pump 202, a loop filter 204, a voltage-controlled oscillator (VCO) 206, a prescaler 208, and an accumulator 210. It should be appreciated that alternate implementations of the fractional-N mode of the hybrid PLL may be configured with more or less elements than shown in FIG. 2A; in particular, the elements 200-210 of the circuit of FIG. 2A may be implemented in any suitable manner, examples of which are discussed below in conjunction with FIG. 4.

Notably, fractional spur suppression circuits such as phase interpolators or high-order ΣΔ (sigma-delta) modulators, which may be found in conventional fractional-N PLLs, are not needed in the hybrid PLL. This is because the fractional-N mode is used only during transient states while spurs matter only in steady state. The circuit of FIG. 2A has the reference frequency of f_{REF}=f₀, where f₀ is the frequency of a crystal oscillator signal, and the circuit's standard accumulator-prescaler combination yields a fractional frequency division ratio of N+k/M. Here, N and M are fixed integers that are chosen in the design process; k is a running integer, e.g., k=0, 1, 2, . . . , kₘₐₓ and is used to select a channel. Therefore, the set of output frequencies is given by (N+k/M)f₀ as a function of k. The output frequency resolution is f₀/M.

To make the hybrid PLL approach possible, when the fractional-N loop of FIG. 2A reaches a phase lock, the loop should be modified to form an integer-N loop. In one embodiment, this is accomplished by inserting a static divider (divide-by-M) 212 and 214 in front of each of the two inputs of the PFD 200, as shown in FIG. 2B. Again, it should be appreciated that the circuit schematic of FIG. 2B is merely exemplary, and that other configurations are possible with more or less elements than shown in FIG. 2B. It should be further appreciated that the elements of the circuit of FIG. 2B may be implemented in any suitable manner.

The reconfiguration of the loop of FIG. 2A into the loop of FIG. 2B creates an integer-N PLL where the reference frequency is f_{REF}=f₀/M and the frequency division ratio provided by the combination of the accumulator 210, the static dividers (divide-by-M) 212 and 214, and the prescaler 208 within the dashed box of FIG. 2B is an integer number of NM+k. Therefore, the reconfigured loop still produces the same set of output frequencies, (N+k/M)f₀, with the same frequency resolution, f₀/M, as in the fractional-N mode of FIG. 2A.

To elucidate how the circuit within the dashed box in FIG. 2B indeed provides an integer frequency division by NM+k, steady-state voltage signals d₁(t)+d₂(t) at different nodes in the circuit of FIG. 2B are shown in FIG. 2C with N=4, M=5 and k=1 as an example.

The NM+k division block within the dashed box of the integer-N modes in FIG. 2B may be rather unfamiliar as it is different from the conventional integer-N PLL's NM+k division block as shown in FIG. 2D. The conventional circuit of FIG. 2D comprises a swallow counter 220, a static divider (program counter, divide-by-M) 216, and a prescaler 218. The primary difference between the circuits of FIGS. 2B and 2D arises from the use of an accumulator 210 in the hybrid PLL as opposed to the use of a swallow counter 220 in the conventional integer-N PLL.

It should be noted that the integer-N mode of FIG. 2B has a greater degree of hardware complexity than the fractional-N mode of FIG. 2A. The fundamental reason for this is the absence of any fractional spur suppression circuit in the fractional-N mode. Thus, in exemplary implementations, an overall hybrid PLL architecture incorporating both modes in a single loop would have the same-level of hardware complexity as the normal integer-N PLL.

It should also be appreciated from the foregoing discussions that the simple switching from the fractional-N loop of FIG. 2A to the integer-N loop of FIG. 2B is made possible by this exception of the fractional spur reduction scheme employed in the fractional-N loop and by replacing the standard pulse swallow counter 220 used for integer frequency division with an accumulator 210 conventionally used for simplified fractional frequency division.

In one embodiment of the present invention, the frequency division mode switching in the hybrid PLL is executed in parallel with the bandwidth switching explained above; however, it should be appreciated that this switching protocol is merely illustrative and that frequency division mode switching of the hybrid PLL may be done in any suitable manner (e.g., frequency division mode switching may be done after the bandwidth switching).

The exemplary protocol for executing bandwidth switching in parallel with frequency division mode switching starts with the same bandwidth switching principle as in the original variable-bandwidth PLL work described above, i.e., changing an open loop bandwidth while maintaining the same open loop phase margin to maintain the same level of stability across the steady-state and transient operation.

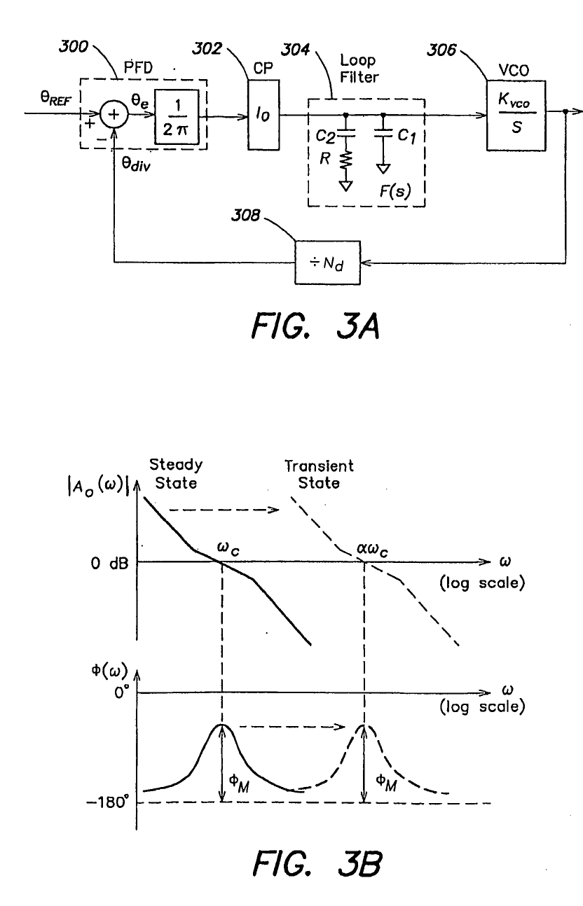

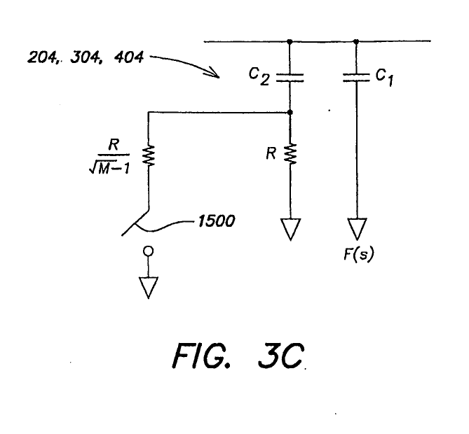

FIG. 3A shows a simplified charge-pump PLL frequency synthesizer circuit with a 2nd-order loop filter in accordance with embodiments of the present invention. The circuit of FIG. 3A comprises a PFD 300, charge pump 302, loop filter 304, VCO 306, and prescaler 308. It should be appreciated that alternate configurations of the hybrid PLL may be implemented with more or less elements than shown in FIG. 3A. It should be further appreciated that the elements of the circuit of FIG. 3A may be implemented in any suitable manner and are not limited to the implementations depicted in FIG. 3A.

The frequency division ratio, N_{d}, can be either an integer or a fractional number. The open-loop transfer function of this exemplary synthesizer is given by

$${A}_{o} ( s ) = \frac{{θ}_{div} ( s )}{{θ}_{REF} ( s )} = \frac{{K}_{VCO}}{2 π} \cdot \frac{{I}_{0}}{{N}_{d}} \cdot \frac{F ( s )}{s} . \qquad ( 1 )$$

Here K_{VCO} is the VCO gain, I₀ is the charge-pump current, and F(s) is the input impedance of the 2nd-order loop filter expressed as

$$F ( s ) = \frac{1}{s ( {C}_{1} + {C}_{2} )} \cdot \frac{1 + {sRC}_{2}}{1 + {sRC}_{∥}} , \qquad ( 2 )$$

where C_{∥}≡C₁C₂/(C₁+C₂). The magnitude and phase of Aₒ(ω) (s=jω) are then given by:

$$\begin{matrix}\vert {A}_{o} ( ω ) \vert = \frac{{K}_{VCO}}{2 π ( {C}_{1} + {C}_{2} )} \cdot \frac{{I}_{0}}{{N}_{d}} \cdot \sqrt{\frac{1 + {( ω {RC}_{2} )}^{2}}{1 + {( ω {RC}_{∥} )}^{2}}} \cdot \frac{1}{{ω}^{2}} & ( 3 ) \\ φ ( ω ) \approx {tan}^{- 1} ( ω {RC}_{2} ) - {tan}^{- 1} ( ω {RC}_{∥} ) - {180}^{°} . & ( 4 )\end{matrix}$$

The Bode plots of |Aₒ(ω)| and φ(ω) are shown with solid lines in FIG. 3B, where the unity gain frequency is denoted as ω_{c} and the phase margin at ω=ω_{c} is signified by φ_{M}. In the Bode plots, C₁<<C₂ was assumed so that the pole, 1/RC_{∥}˜1/RC₁, is clearly separated from the zero, 1/RC₂. However, embodiments of the invention are not limited to implementing a second-order filter having C₁<<C₂, as any suitable filter may be used in accordance with embodiments of the present invention.

According to the bandwidth switching principle of the variable-bandwidth PLL, the bandwidth is increased by a factor of α at the onset of a transient state while keeping the same phase margin of φ_{M} to preserve the same level of stability. This may be done in any suitable manner, including, for example, by simultaneously executing the following two adjustments using three loop parameters, R (loop filter resistance), I₀, and N_{d}:

$$\{ \begin{matrix}Adjustment A \text{:} \underline{Reduction of R by a factor of α .} \\ Adjustment B \text{:} \underline{Increase of {I}_{0} / {N}_{d} by a factor of {α}^{2} .}\end{matrix}$$

These loop parameter adjustments lead to replacement of ω in equations (3) and (4) with ω/α. This resealing of ω corresponds to parallel translation of the Bode plots by log α along the ω axis in the log scale, resulting in the dashed lines in FIG. 3B. These parallel translations of the Bode plots produce two results: (1) the change of the unity gain frequency from ω_{c} to αω_{c} corresponds to the proportional bandwidth enhancement, and (2) the phase margin at the new unity gain frequency is the same as that at the old unity gain frequency.

These parameter adjustments for bandwidth enhancement were derived quite generally, and are applicable not only to the hybrid PLL but also to the conventional variable-bandwidth PLL with a fixed frequency division mode, as has been demonstrated. In conventional V-BW PLLs, the latter, however, it should be appreciated that changing N_{d} is not an option, and parameters used for the two adjustments in such conventional PLLs are limited to the charge-pump current I₀ and the loop filter resistance, R.

In contrast, in the hybrid PLL, the increase of bandwidth at the onset of a transient is accompanied by the automatic reduction of N_{d} by a factor of M as the frequency division mode is also shifted from integer-N (division ratio: NM+k) to fractional-N (division ratio: N+k/M). As a result, the hybrid PLL offers a new protocol for altering the bandwidth, which not only uses the conventional parameters (I₀ and R) but also exploits the automatic change in N_{d} as an additional parameter. In this protocol, N_{d} and I₀ are controlled interdependently for a given a since it is I₀/N_{d} that is used to execute Adjustment B. Below are two specific examples of how the parameter adjustments for bandwidth switching above can be applied to the hybrid PLL, considering the automatic reduction in N_{d}.

### Example 1

Here I₀ is kept constant and only the automatic reduction in N_{d} is exploited to execute Adjustment B. It should be appreciated that this is a polar opposite of the bandwidth switching protocol in the conventional variable-bandwidth PLL where I₀ must be increased to execute Adjustment B as N_{d} is fixed. Since in this example 10 is maintained the same but N_{d} is automatically reduced by a factor of M, Adjustment B is naturally performed with α=\sqrt{M}. Adjustment A then can be performed by decreasing R by a factor of \sqrt{M} by designing the loop filter of FIG. 3A as shown in FIG. 3C and closing the switch 1500 when the synthesizer is switched to the fractional-N mode at the onset of a transient. With I₀ held constant and entirely relying on N_{d} for Adjustment B, this example represents a bandwidth switching protocol that is more digital than any other parameter adjustment possibilities. This implementation is discussed in more detail below.

### Example 2

The Example above focused on a digital bandwidth switching maintaining a constant charge pump current. Alternatively, by not only exploiting the automatic reduction in N_{d} by a factor of M but also altering I₀, one can attain the highest bandwidth possible during transient, which is discussed in this example. Here the transient bandwidth of the fractional-N mode is maximized to 10 percent of the reference frequency of the fractional-N mode to ensure the loop stability as discussed above (i.e., the bandwidth is given by f₀/10 where f₀ is with reference to FIG. 2A). For the steady-state bandwidth of the integer-N mode to achieve the optimum spectrum, although it varies from design to design, 5 percent of the reference frequency of the integer-N mode may be chosen (i.e., f₀/(20M)) as a rough estimate in the initial design phase. With the above choices of the transient and steady-state bandwidth, α=2M. The bandwidth switching factor of 2M in this example is larger than the bandwidth switching factor of \sqrt{M} in Example 1 above. This improvement in the amount of the bandwidth increase in this example is attributed to not holding I₀ at a constant value. Because α=2M, to perform Adjustment A, the loop filter resistance should be decreased by a factor of 2M, and to perform Adjustment B, the charge pump current I₀ should be increased by a factor of 4M because N_{d} is automatically reduced by a factor of M. It should be appreciated that in the conventional variable-bandwidth PLL where N_{d} is fixed, increasing the bandwidth by the same factor of α=2M as in this example requires that the charge pump current be increased by a much larger factor of 4M².

Having discussed operating principles of the hybrid PLL, the overall architecture of the PLL may be described. FIG. 4 schematically shows an exemplary hybrid PLL frequency synthesizer made by combining the fractional-N mode of FIG. 2A and the integer-N mode of FIG. 2B in a single loop and simultaneously incorporating the bandwidth switching. It should be appreciated that the circuit of FIG. 4 is merely illustrative and that embodiments of the invention are not limited to implementing the circuit of FIG. 4, as any suitable circuit may be implemented in accordance with embodiments of the invention.

The circuit of FIG. 4 comprises a PFD 400, a charge pump 402, a loop filter 404 implemented according to the circuit of FIG. 3C or in any other suitable manner, and a VCO 406. The circuit further comprises prescaler 408 and static dividers 412 and 414, as well as accumulator 410. Additionally, the circuit comprises a lock timer 420 and multiplexers 416 and 418.

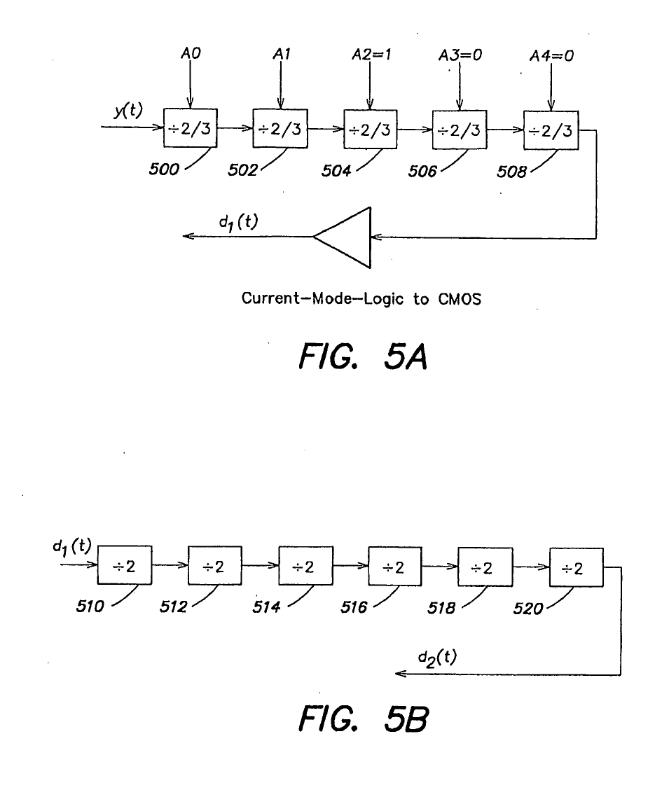

The prescaler 408 of FIG. 4 may be implemented in any suitable manner, for example, as a chain of five dual-modulus divide-by-2/3 blocks 500-508 as shown in FIG. 5A. The division ratio of each of the first two dual-modulus blocks is controlled by the variable accumulator output (A₀ or A₁) and also by the signal from its preceding block. The division ratio of each of the other three dual-modulus components is controlled by its fixed control bit (A₂=1, A₃=0, or A₄=0) and also by the signal from its preceding dual-modulus block. This configuration results in a prescaler division ratio of N=Σₘ₌₀⁴Aₘ·2^{m}+32=36+A₀+2A₁, which runs from 36 to 39 with the four different combinations of A₀ and A₁ values. The static dividers (divide-by-M blocks) 412 and 414 of FIG. 4 also may be implemented in any suitable manner, and an exemplary implementation of the dividers as a chain of standard D-flip-flop-based divide-by-2 circuits 510-520 is shown in FIG. 5B. It should be appreciated, however, that the circuits of FIGS. 5A and 5B are merely illustrative, and embodiments of the invention are not limited to implementing the circuits shown in FIGS. 5A and 5B.

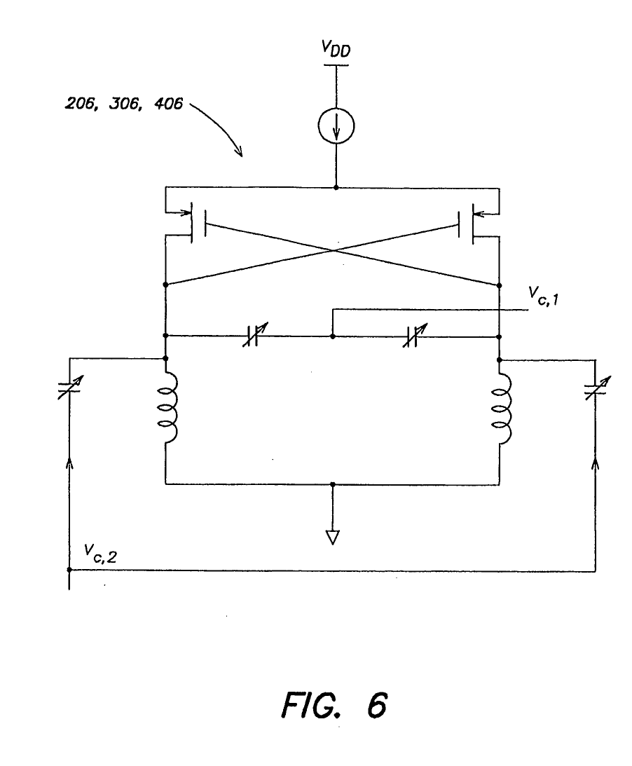

A PMOS-only cross-coupled LC voltage controlled oscillator as shown in FIG. 6 may be implemented as the VCO 406. The VCO of FIG. 6 not only has a standard voltage control input (V_{c,1}) driven by the loop filter output but also incorporates a coarse voltage control input (V_{c,2}) to externally adjust the oscillation frequency range for a reasonably large process variation. The VCO gain is about 250 MHz/V for the main control input. It should be appreciated, however, that the VCO 406 may be implemented in any suitable manner, and is not limited to being implemented as the circuit of FIG. 6.

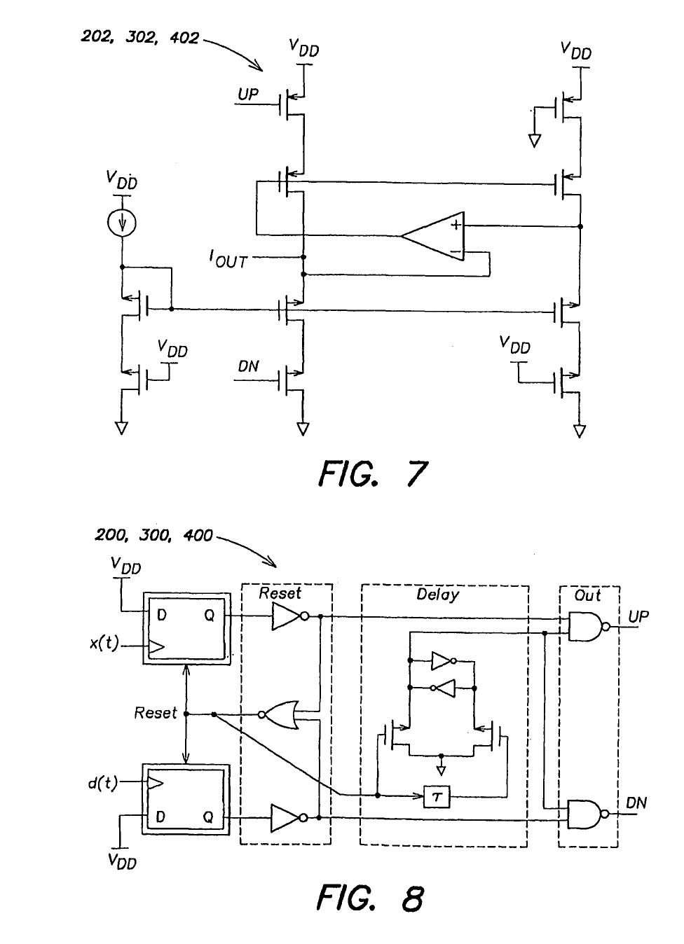

FIG. 7 illustrates an exemplary implementation of a charge pump 402 in accordance with embodiments of the present invention. The circuit of FIG. 7, with a replica biasing scheme utilizing an operational amplifier in a feedback loop, reduces charge-pump current mismatches which otherwise can cause significant reference spurs. Again, it should be appreciated that this implementation is merely illustrative, and other implementations are possible.

FIG. 8 depicts one implementation of a PFD 400 in accordance with embodiments of the invention. A reset delay is frequently inserted in a conventional PFD to eliminate a dead zone of charge-pump circuits. The finite reset delay, however, undesirably makes the PFD miss one of its input clock edges periodically during a frequency acquisition, and may compromise the locking speed. To alleviate this effect, the circuit of FIG. 8 separates the reset and delay functions as shown. It should be appreciated, however, that other solutions to the finite reset delay difficulty are possible and thus other circuits may be implemented in accordance with embodiments of the invention. Further, PFD circuits that do not require a finite reset delay may be implemented in embodiments of the invention, and it should be appreciated that embodiments of the present invention are not limited to implementing the circuit of FIG. 8.

As noted above, the design simplicity of the circuit depicted in FIG. 4 is attained because no fractional spur reduction scheme (phase interpolators or high-order EA modulators) is needed in the transient fractional-N mode as spurs matter only in steady state, as discussed in greater detail below. Due to the absence of the fractional spur reduction circuits, the switching between the two frequency division modes is executed by a reconfiguration of only a couple of components in a single loop, and the overall architecture is almost a simple integer-N loop.

When the synthesizer of FIG. 4 enters a transient state, the two divide-by-M blocks 412 and 414 are disabled and screened out by the two multiplexers 416 and 418 shown inside the shaded areas, and the input signal (crystal oscillator signal), x(t), whose frequency is f₀ and the prescaler 408 output, d₁(t), are directly fed to the two inputs of the PFD 400. This operation mode is equivalent to the fractional-N loop of FIG. 2A. When the synthesizer attains a phase lock (which is signaled by the lock timer 420 shown inside another shaded area in FIG. 4), the two divide-by-M blocks 412 and 414 are enabled and the two multiplexers 416 and 418 select the outputs of the two divide-by-M blocks 412 and 414 as inputs of the PFD 400. The resulting circuit is equivalent in behavior to the integer-N loop of FIG. 2B. The switch 1500 in the loop filter 404 is open in the integer-N mode, and remains closed in the fractional-N mode. Due to the constant charge-pump current, there is no switch associated with the charge pump 402.

As noted above, the overall architecture is similar to a normal integer-N PLL, but has several marked differences. First, the circuit within the dashed box of FIG. 4 comprising the accumulator 410, divide-by-M 414, and prescaler 408, which performs the integer divide-by-(NM+k) through the output d₂(t), is similar to the more standard integer divide-by-(NM+k) circuit comprising a pulse swallow counter 220, divide-by-M 216, and prescaler 218 shown in FIG. 2D. Differences may be seen in the accumulator and the swallow counter, but they have the same level of hardware complexity. Second, the divide-by-M block 412 in the upper portion of FIG. 4 is similar to the reference divider in standard integer-N PLLs, which is commonly used in high frequency resolution applications. Therefore, the hybrid PLL of FIG. 4 is architecturally similar to the conventional integer-N PLL, having only three additional components (the two multiplexers 416 and 418 and the lock timer 420), which may be implemented as simple digital logic gates and programmable counters or in any other suitable manner. This similarity is due, as noted above, to the absence of any fractional spur suppression circuit in the hybrid PLL.

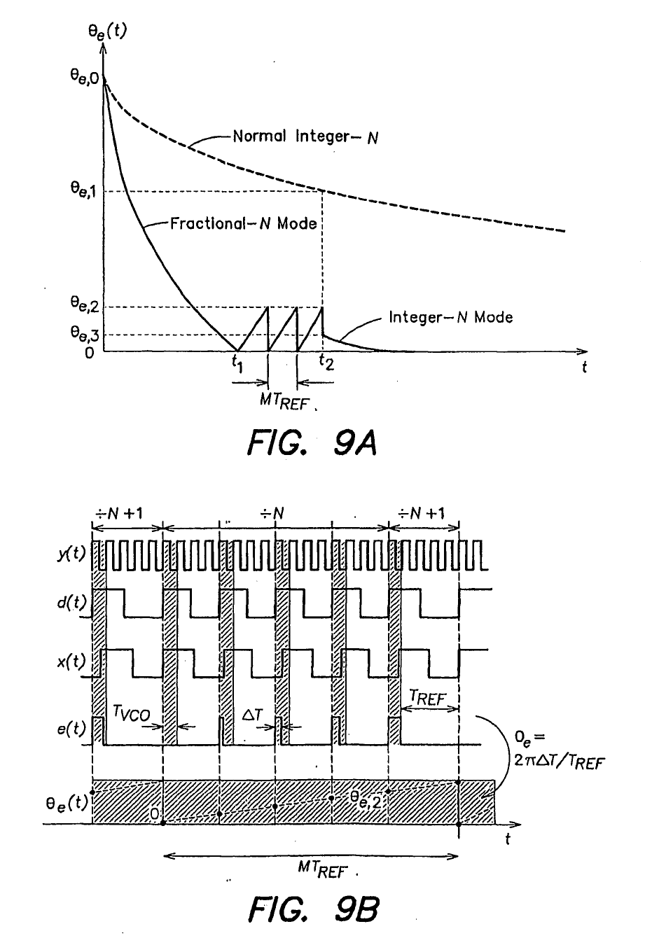

FIG. 9A illustrates the locking speed of the hybrid PLL which results from the combination of the integer-N and fractional-N PLLs by comparing the lock behavior of the hybrid PLL (solid curve) to that of the normal integer-N PLL (dashed curve). The loop bandwidth of the normal integer-N PLL is equal to the loop bandwidth of the hybrid PLL at its steady-state, integer-N mode operation. In the figure, the vertical axis is the phase error, θₑ, obtained from the PFD output, e(t) (see FIG. 2A), and the horizontal axis is the time, t. When the two synthesizers start from the same phase error, θ_{e,0}, the phase error of the hybrid PLL reduces towards zero faster than that of the normal integer-N PLL, because of the wider loop bandwidth of the former during its transient fractional-N mode operation.

An important premise for the fast locking PLL via the hybrid approach is that at the moment the fractional-N mode is switched to the integer-N mode at the onset of a phase lock, the phase error should not jump to a large value. More specifically with reference to FIG. 9A, when the hybrid PLL switches from the fractional-N mode to the integer-N mode (say, at t=t₂) after it acquires a phase lock, the new phase error, θ_{e,3}, of the integer-N mode should not pop back up to exceed the phase error, θ_{e,1}, of the normal integer-N PLL at the same time of t=t₂. If this happened, the fast locking purpose of the hybrid PLL would be entirely defeated.

Because the fractional-N mode of the hybrid PLL does not incorporate any fractional suppression circuit, once it enters a steady state with a phase lock at t=t₁, the phase error θₑ does not settle to zero but it rather exhibits a small oscillation between 0 and a certain maximum value, θ_{e,2}, as shown with the zigzag pattern in FIG. 9A, which corresponds to fractional spurs in the frequency-domain. FIG. 9B illustrates more details of this phase error oscillation along with other relevant signals (with N=4, M=5, and k=1). It should be appreciated that the illustrated waveforms are based on the often-used simplified analysis assuming that the loop is disconnected at the junction between the charge-pump and the loop filter after the fractional-N PLL reaches a phase lock. While this is not the most rigorous analysis—in a more rigorous picture, the phase error would oscillate not between 0 and a positive maximum, but rather between a negative minimum and a positive maximum—it captures the essence of the steady-state behavior of the fractional-N PLL. The phase error θₑ=2πΔT/T_{REF} of the error signal e(t), which appears once in every period of the reference signal x(t), continually grows up to θ_{e,2} given by

$$\begin{matrix}{θ}_{e , 2} ∼ 2 π \cdot \frac{{( Δ T )}_{max}}{{T}_{REF}} \\ = 2 π \cdot \frac{M - 1}{M} {T}_{VCO} \cdot \frac{1}{{T}_{REF}} \\ ∼ 2 π \cdot \frac{M}{NM + k}\end{matrix} \qquad ( 5 )$$

until the prescaler is reset to return the phase error to zero. This growth dynamic repeats itself with the period of M/f_{REF}=M/f₀, corresponding to the zigzag pattern in FIG. 9A.

When the fractional-N loop of FIG. 2A is reconfigured to form the integer-N mode of FIG. 2B at t=t₂ as in FIG. 9A (this is the worst case scenario as the switching occurs when the phase error assumes the maximum value, θ_{e,2}) the new phase error, θ_{e,3}, is given by

$${θ}_{e , 3} = \frac{1}{M} \cdot {θ}_{e , 2} \qquad ( 6 )$$

because the reference frequency f_{REF} is decreased by a factor of M while ΔT remains almost the same right after the switching. This means that there will not be a large phase error disturbance at all but rather θ_{e,3} will be always smaller than θ_{e,2}. In addition, since θ_{e,2}<θ_{e,1} can be safely assumed because the fractional-N mode is reasonably faster than the normal integer-N PLL, it follows that θ_{e,3}<θ_{e,1} and the hybrid PLL settles significantly faster than the normal integer-N PLL, as shown in FIG. 9A. Moreover, by combining equations (5) and (6), we obtain

$${θ}_{e , 3} = 2 π \cdot \frac{1}{NM + k} \qquad ( 7 )$$

which means that θ_{e,3} will be not only smaller than θ_{e,2} but also significantly smaller than 2π for practical choice of values for N, M, and k.

The foregoing discussion clearly shows that the shift from fractional-N to integer-N makes the phase error undergo a significant reduction instead of a disturbance, owed to the inherently different nature between the two division modes. Thus, the dynamics at the mode changing moment do not compromise but rather enhance the power of the hybrid-PLL approach.

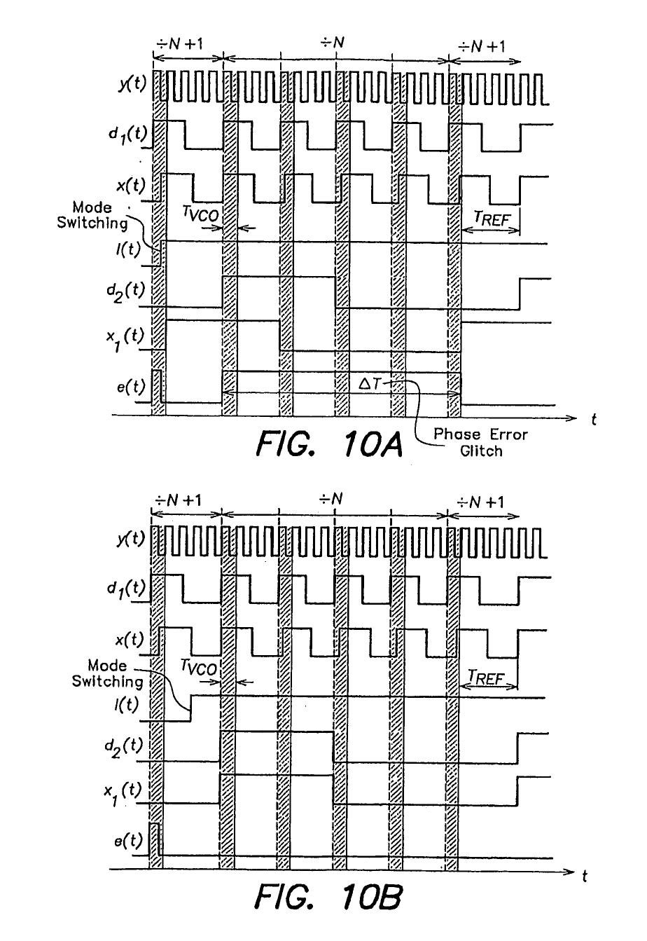

In practice, however, the mode switching time should be carefully chosen to ensure that ΔT right before the mode switching remains more or less the same in the next phase comparison event immediately following the mode switching, which was the basic assumption to obtain equation (6). To see this clearly, an example is provided in which the mode switching time is ill-chosen. If the mode switching takes place during the phase comparison as in FIG. 10A, i.e., if the lock timer output l(t) signals a mode switching (by rising from zero to one) after the rising edge of d₁(t) but before the rising edge of x(t), the PFD will miss the input rising edge of x(t). As a result, the outputs of the two static dividers in FIG. 4 are misaligned, generating a large ΔT in the phase comparison period following the mode switching, as shown in FIG. 10A. This phase error glitch can be avoided by synchronizing the mode switching time with the falling edge of either x(t) or d₁(t) as shown in FIG. 10B. With the synchronization, ΔT will remain the same right after the switching, justifying (6). In FIG. 10B, the picture was simplified by assuming a lock acquisition right after the switching into the integer-N mode, and by making ΔT=0.

Another physical mechanism that can give rise to a phase error glitch at the switching moment is provided by a parasitic capacitance bypassing the physical switch in the loop filter of FIG. 4, and a careful physical layout is required in general to minimize the parasitic capacitance. In a CMOS integrated circuit implementation, the parasitic capacitance of the switch may be much smaller than the loop filter capacitances, and hence, the effect may be negligible.

In particular, a CMOS-implemented hybrid PLL according to one embodiment of the present disclosure does not exhibit any discernable phase error perturbations at the switching moment. In this embodiment, the hybrid PLL is designed and fabricated in TSMC 0.18 μm mixed-signal CMOS technology. The architecture shown in FIG. 4 is implemented such that the frequency division mode switching takes place in synchronism with the digital bandwidth switching (constant charge-pump current). The previously-mentioned countermeasures to prevent possible phase error glitch events at switching moments are incorporated.

In a practical, exemplary CMOS implementation of the hybrid PLL according to this embodiment, the overall IC for the PLL, including bonding pads and electrostatic discharge protection circuits, occupies an area of 1.6×1.3 mm². Most of the components of FIG. 4 may be implemented on chip. Off-chip components may be the crystal oscillator 406, the lock timer 420, and most of the loop filter 404. The IC is mounted on a 10-mm LQFP 44-pin package, which in turn is mounted on a printed circuit board for characterization purposes. The lock timer 420 is implemented on the same printed circuit board using discrete components, and is driven by a function generator. The IC is powered with a 1.8-V power supply.

TABLE 1
Hybrid-PLL Frequency & Bandwidth Setup,
and Settling-Time Measurement Results
Frequency synthesis plan (hybrid PLL)

| | |
|---|---|
| f_{REF} (Tracking, fractional-N) | 64 MHz |
| f_{REF} (Locked, integer-N) | 1 MHz |
| N₁, M, k | 37, 64, {0, 1, . . . , 63} |
| N₂, M, k | 38, 64, {0, 1, . . . , 63} |
| N₃, M, k | 39, 64, {0} |
| Number of channels | 129 |
| Channel spacing | 1 MHz |
| Output frequencies | 2.368~2.496 GHz |

Bandwidth setup (hybrid PLL)

| | |
|---|---|
| Loop bandwidth (Tracking) | 400 kHz |
| Loop bandwidth (Locked) | 50 kHz |
| α (BW enhancement factor) | \sqrt{M} = 8 |

Settling-time measurement results

| | |
|---|---|
| Hybrid-PLL | ~20 μs |
| Normal Integer- N PLL | ~80 μs |

The target frequency synthesis plan for the CMOS prototype is summarized at the top portion of Table 1. As shown, to limit the maximum number for k (the accumulator input) to 63 but to create 129 channels, three N values are used. The CMOS IC successfully synthesizes the desired set of output frequencies. Since M=64 and the digital bandwidth-switching protocol is used with a constant charge-pump current (see Example 1 above) with this specific implementation, the bandwidth enhancement factor α is \sqrt{M}=8, and accordingly the transient and steady-state loop bandwidths are set up as shown in the middle portion of Table 1. The steady-state bandwidth of 50 kHz in the integer-N mode is set at 5 percent of the reference frequency of the integer-N mode (1 MHz), which is the value often used as an initial choice of the integer-N mode bandwidth.

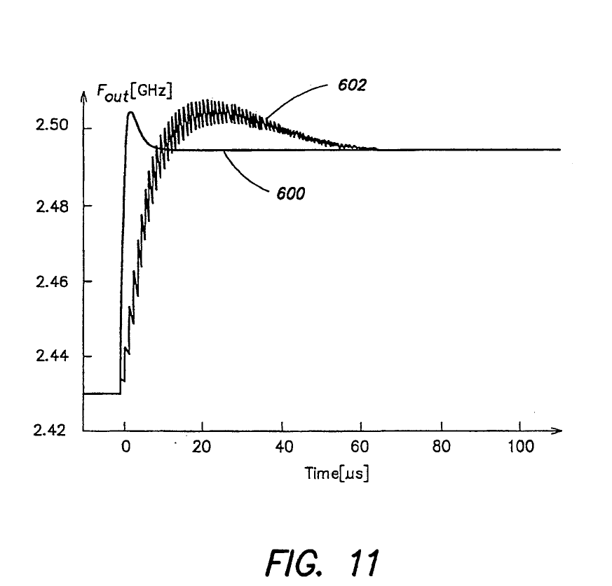

A measurement of locking transient of the hybrid-PLL was performed by exciting the system with a 64 MHz frequency step (from N=37, k=62 to N=38, k=62, i.e., from 2.430 GHz to 2.494 GHz). The line 600 of FIG. 11 shows the frequency settling transient of the hybrid-PLL measured using an Agilent E5052A signal source analyzer. The operation mode and bandwidth of the hybrid PLL were simultaneously switched from the fractional-N mode (400 kHz bandwidth) to the integer-N mode (50 kHz bandwidth) at t=10 μs. This switching time was manually determined by first running the hybrid-PLL in its fractional-N mode without a switching operation, and estimating its settling time. The lock timer operates based on this pre-determined switching time. As seen with the 600 line in FIG. 11, no discernable phase disturbance is observed at the switching moment, and the frequency settling time for the hybrid PLL is about 20 μs.

For comparison purposes, with the same frequency step excitation, the locking transient of a normal integer-N PLL, which is derived from the hybrid-PLL by constantly operating it in its integer-N mode without employing the mode and bandwidth switching, was also measured. The 602 line of FIG. 11 shows the measured locking transient for the normal integer-N PLL. The frequency settling time is approximately 80 μs, which is 4 times larger than that of the hybrid PLL. This comparative characterization of the two PLLs clearly affirms the validity of the fast locking approach via the hybrid PLL.

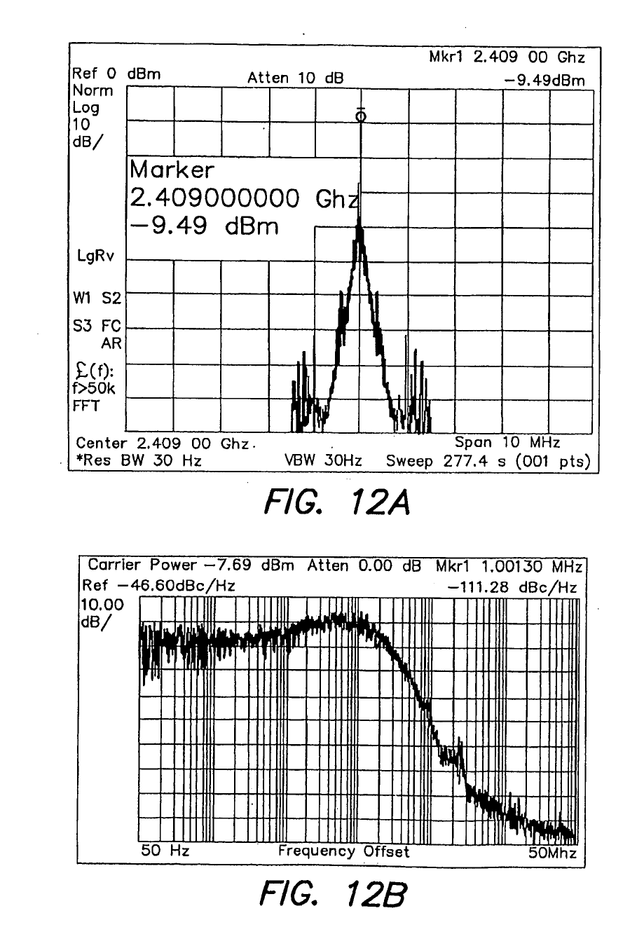

Other measured aspects of the hybrid PLL are briefly summarized below in Table 2. FIG. 12A is a power spectral density of the hybrid PLL (at its steady-state integer-N mode) measured using an Agilent E4448A spectrum analyzer when N=37 and k=41 (2.409 GHz of output frequency). This measurement clearly demonstrates the desired frequency synthesis with the 1-MHz frequency resolution as planned in the top portion of Table 1. The fundamental reference spur does appear at 1 MHz, and is −54 dBc.

TABLE 2
Other Measurement Results
Measured spectral data (@ 2.409 GHz)

| | | |
|---|---|---|
| Reference spur @ 1 MHz | −54 | dBc |
| Phase noise @ 1 MHz | −111.3 | dBc/Hz |

Power dissipation

| | | |
|---|---|---|
| VCO | 6.3 | mW |
| VCO buffer | 13.8 | mW |
| Prescaler | 8.6 | mW |
| Charge-pump | 0.4 | mW |
| Total | 29.6 | mW |

FIG. 12B is a corresponding phase noise plot at the same output frequency of 2.409 GHz, which was measured using the built-in phase noise measurement capability of the Agilent E4448A spectrum analyzer. As mentioned earlier, the steady-state bandwidth of the integer-N mode was chosen at 5 percent (50 kHz) of its reference frequency without much bandwidth optimization for optimum spectrum. Thus, the rather large input referred noise was not fully suppressed by the steady-state integer-N mode, and consequently the phase noise plot exhibits the −40 dB/dec slope of the 2nd-order loop filter around the frequency range from 100 kHz to 1 MHz. At higher frequencies, the phase noise plot follows the −20 dB/dec slope, which corresponds to the high-pass filtered phase noise of the voltage-controlled oscillator. The phase noise can be further optimized by properly choosing the steady-state bandwidth of the integer-N mode and by reducing the component noise, without afflicting the hybrid-PLL operation as the latter is independent of the phase noise optimization. Table 2 summarizes the measured, spectral data as well as the component-by-component breakdown of the power consumption.

In sum, the concepts underlying various embodiments of hybrid PLLs according to the present disclosure extend the conventional variable-bandwidth PLL scheme by incorporating frequency division mode switching in synchronism with the bandwidth switching. The primary advantages, as detailed above lie in simultaneous achievement of fast locking (fractional-N property) and design simplicity (integer-N property), and execution of the bandwidth switching with more design parameters, which offers a more powerful digital protocol for the bandwidth switching.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. An apparatus to synthesize a frequency, comprising:
a phase-frequency detector (PFD) to receive a first and a second input;
a charge pump coupled to the PFD;
a loop filter coupled to the charge pump;
a voltage-controlled oscillator (VCO) coupled to the loop filter;
a feedback loop coupled to the VCO and the second input of the PFD, the feedback loop comprising:
at least one accumulator;
at least one multiplexer that provides the second input to the PFD; and
at least one static divider coupled to the multiplexer and configured to manipulate the second input to the PFD; and
a lock timer to control the at least one multiplexer.

2. The apparatus of claim 1, further comprising a crystal oscillator to provide the first input to the PFD.

3. The apparatus of claim 1, further comprising at least one second multiplexer disposed between the crystal oscillator and the PDF that provides the first input to the PFD.

4. The apparatus of claim 3, further comprising at least one second static divider coupled to the at least one second multiplexer and the crystal oscillator and configured to manipulate the first input to the PFD.

5. The apparatus of claim 4, wherein the lock timer is configured to control the at least one multiplexer and the at least one second multiplexer such that the apparatus operates in both a fractional-N mode and an integer-N mode.

6. The apparatus of claim 1, wherein the lock timer is configured to control the at least one multiplexer such that the apparatus operates in both a fractional-N mode and an integer-N mode.

7. A method comprising:
(A) operating a PLL circuit in a first frequency division mode during a transient state; and
(B) operating the PLL circuit in a second frequency division mode once the PLL circuit reaches a steady state.

8. The method of claim 7, further comprising:
(C) altering the bandwidth of the PLL circuit when the PLL circuit reaches a steady state.

9. The method of claim 8, wherein the act (C) comprises reducing the bandwidth.

10. The method of claim 8, wherein the acts (B) and (C) are performed at essentially the same time.

11. The method of claim 8, wherein the acts (A), (B), and (C) are performed without altering the phase margin of the PLL circuit.

12. The method of claim 7, wherein the first frequency division mode is a fractional-N frequency division mode and the second frequency division mode is an integer-N frequency division mode.

13. The method of claim 7, wherein the act (B) is performed in synchronism with the falling edge of an input signal.

14. An phase-locked loop apparatus comprising:
a phase-frequency detector (PFD) to receive a first and a second input;
a charge pump coupled to the PFD;
a loop filter coupled to the charge pump;
a voltage-controlled oscillator (VCO) coupled to the loop filter; and
a controller to change an operating mode of the apparatus between a fractional-N mode and an integer-N mode.

15. The apparatus of claim 14, further comprising a crystal oscillator to provide the first input to the PFD.

16. The apparatus of claim 15, further comprising at least one second multiplexer disposed between the crystal oscillator and the PFD that provides the first input to the PFD.

17. The apparatus of claim 16, further comprising at least one second static divider coupled to the at least one second multiplexer and the crystal oscillator and configured to manipulate the first input to the PFD.

18. The apparatus claim 17, wherein the lock timer is configured to control the at least one multiplexer and the at least one second multiplexer such that the apparatus operates in both a fractional-N mode and an integer-N mode.

19. The apparatus of claim 14, wherein the controller comprises at least one multiplexer that provides the second input to the PFD and a lock timer to control the at least one multiplexer.

20. The apparatus of claim 19, wherein the lock timer is configured to control the at least one multiplexer such that the apparatus operates in both a fractional-N mode an integer-N mode.
